(19) United States
(12) Patent Application Publication
(10) Pub. No.: US 2011/0253186 A1
(43) Pub. Date: Oct. 20, 2011

(54) Combined Thermoelectric and Thermomagnetic Generator

(75) Inventors: Ingo Bayer, London (GB); Bruce Ringsby Olmstead, Pretoria (ZA)

(73) Assignee: BHP Billiton ALuminium Technologies Limited, Jersey (GB)

(21) Appl. No.: 13/120,962

(22) PCT Filed: Oct. 27, 2009
(86) PCT No.: PCT/EP2009/064143

§ 371 Date: Jul. 6, 2011

(30) Foreign Application Priority Data
Oct. 28, 2008 (AU) 2008905553
Nov. 12, 2008 (AU) 2008905856

(51) Int. Cl. H01L 35/32; H02N 10/00; H01L 37/00

(52) U.S. Cl. 136/205; 310/306

(57) ABSTRACT

A thermoelectric device (100) including a combination of thermoelectric elements (60, 62) and thermomagnetic elements (65) may be applied to a pyrometallurgical processing structure (20) whose operation generates a magnetic field. The generation and existence of the magnetic field provides an increase in the electrical energy generated over operation when the field does not exist. The device enhances overall cell efficiency by recovery of electrical energy from lost diffuse heat, while simultaneously enhancing the efficiency of the heat recovery through the effects of existing magnetic fields and improving control of freeze layer formation, in an electrolytic cell for aluminium production.

### FIELD OF THE INVENTION

This invention relates to a thermoelectric and thermomagnetic device for extracting usable energy from waste heat.

### BACKGROUND OF THE INVENTION

Thermoelectric devices or Seebeck devices are devices which convert temperature differences between opposite sides of the device to electrical energy. Typically made from semi-conducting metals or semi-metals, Seebeck devices are generally wafer-shaped and rely upon the imposition of a temperature difference across their opposing major surfaces as the source of the electrical current they develop. Although berated in the past as being inefficient, recent advances in materials and materials processing have led to significant improvements in efficiency. Moreover, even as historically inefficient power generators, they are still able to access otherwise unavailable energy in an inexpensive, clean and maintenance-free manner. In addition to energy recovery, the use of Seebeck devices on metallurgical vessels may have the added advantage of assisting with the controlling cooling effects of the reaction or processing occurring in the vessel.

To date these devices have been primarily used to convert waste heat from automotive exhaust gases to electrical energy. These devices have not been widely used for the recovery of power from waste heat in pyrometallurgical applications due to their relatively inefficient conversion of heat to electrical energy in industries accustomed to historically cheap and readily available electrical power. Present pyrometallurgical processing vessel designs also more readily lend themselves to high production, rather than concentrating on economy of power usage, thereby further discouraging energy recovery attempts.

Semiconductor thermoelectric devices are generally made from alternating p-type and n-type semiconductors connected by a metallic interconnect; electrons flow through the n-type thermoelectric semiconductor, cross a metallic interconnect and pass into the p-type thermoelectric semiconductor. When a heat source is provided, crystalline dislocations in the p-type thermoelectric semiconductor, move away from the heat source, thereby inducing a flow of electrons towards the heat source. This creates a voltage difference that can be used to create a current and power a load. That is, the thermal energy is converted into electrical energy.

There is a class of thermoelectric materials in which the thermoelectric effect is increased when the material is suitably oriented in a magnetic field. While some enhancement of the thermoelectric effect itself is developed by the magnetic field, appropriate mutual orientation of the magnetic field and temperature gradient offers an additional electric current generated by the Nernst or thermomagnetic effect. This latter current is developed in a direction normal to a mutually perpendicular temperature gradient and magnetic field in the material. Prior art seeking to utilise this increased efficiency of heat conversion have relied on placing the thermoelectric material into a magnetic field provided by a permanent magnet located on either side of the material.

While the invention will be described with reference to vessels for the reduction of alumina to aluminium, it is equally applicable to any structures used in pyrometallurgical processes, which in the context of this invention refers to the thermal treatment of minerals, metallic ores and concentrates to bring about physical and/or chemical transformations in order to enable recovery of valuable metals, and includes but is not limited to drying, calcining, roasting, smelting, fuming and refining (including electrolytic processes). Typically, such processes occur at temperatures in excess of 100° C. This invention specifically is applied to any pyrometallurgical processing structure which generates magnetic fields during its operation and this description of the invention is thus not intended to be limited solely to its use in the aluminium industry. Where suitable magnetic fields exist, this invention can also be applied to energy conversion from hot off-gases from pyrometallurgical processes.

By their nature, aluminium refining and smelting processes have significant power requirements. For instance, during reduction of aluminium oxide (alumina) to form aluminium in electrolytic cells, only about 30% of the total power consumed is actually used by the reduction process with a substantial proportion of the remainder being lost as diffuse heat. A modern, large scale aluminium smelting operation may, through the necessary heating of the reduction environment, in turn lose in excess of 600 MW of energy by natural heat fluxes through the sides and top of the reduction vessels as well as off-gases.

Electrolytic cells for the production of aluminium comprise an electrolytic tank having at least one cathode and anode. The electrolytic tank consists of an outer steel shell having carbon cathode blocks sitting on top of a layer of insulation and refractory material along the bottom of the tank. While the precise structure of the side walls varies, a lining comprising a combination of carbon blocks and refractory material is provided against the steel shell. During the electrolytic process, a large electric current is passed from the anode to the cathode (creating a large magnetic field). Aluminium oxide is dissolved in a cryolite bath present in the tank. The operating temperature of the cryolite bath is normally in the range of 930° C. to about 970° C. Much of the energy required to maintain these process temperatures is lost by diffuse heat fluxes through the refractory lining of the tank.

Apart from this heat loss leading to power inefficiency, the heat transfer and subsequent cooling of the cryolite bath against the refractory lining affects the formation of a layer of ‘frozen’ cryolite bath on the inside of the lining of the electrolytic tank. The thickness of this freeze layer/crust/ledge may vary during operation of the cell, depending for instance on cryolite bath temperature (which is responsive to current flow) and heat removal from the outside of the side walls. If the freeze layer becomes too thick it will affect the operation of the cell as the freeze layer will grow on the cathode and disturb the cathodic current distribution. If the freeze layer becomes too thin or is absent in some places, the cryolite bath may attack the refractory lining and ultimately result in its failure (necessitating its replacement to avoid damage to the steel shell and possible spillage of cryolite bath from the tank). Thus, controlled freeze layer formation is essential for good pot operation and long lifetime of the refractory lining within the cell. Controlled development of the freeze layer can be accomplished in part by suitably manipulating the flow of heat from the bath through the refractory lining of the reduction vessel.

Accordingly, the present invention provides a means for utilizing heat energy lost from the surfaces of a pyrometallurgical processing vessel, such as an electrolysis cell, to enhance its electrical efficiency and, in the case of an electrolysis cell, to provide an improved thermodynamic environment on the inside of the vessel lining such that the formation of a freeze lining may be better controlled.

Reference to any prior art in the specification is not, and should not be taken as, an acknowledgment or any form of suggestion that this prior art forms part of the common general knowledge in Australia or any other jurisdiction or that this prior art could reasonably be expected to be ascertained, understood and regarded as relevant by a person skilled in the art.

### SUMMARY OF THE INVENTION

Thermoelectric devices or Seebeck devices are devices which convert temperature differences between opposite sides of the device to electrical energy. Typically made from semi-conducting metals or semi-metals, Seebeck devices are generally wafer-shaped and rely upon the imposition of a temperature difference across their opposing major surfaces as the source of the electrical current they develop. Although berated in the past as being inefficient, recent advances in materials and materials processing have led to significant improvements in efficiency. Moreover, even as historically inefficient power generators, they are still able to access otherwise unavailable energy in an inexpensive, clean and maintenance-free manner. In addition to energy recovery, the use of Seebeck devices on metallurgical vessels may have the added advantage of assisting with the controlling cooling effects of the reaction or processing occurring in the vessel.

To date these devices have been primarily used to convert waste heat from automotive exhaust gases to electrical energy. These devices have not been widely used for the recovery of power from waste heat in pyrometallurgical applications due to their relatively inefficient conversion of heat to electrical energy in industries accustomed to historically cheap and readily available electrical power. Present pyrometallurgical processing vessel designs also more readily lend themselves to high production, rather than concentrating on economy of power usage, thereby further discouraging energy recovery attempts.

Semiconductor thermoelectric devices are generally made from alternating p-type and n-type semiconductors connected by a metallic interconnect; electrons flow through the n-type thermoelectric semiconductor, cross a metallic interconnect and pass into the p-type thermoelectric semiconductor. When a heat source is provided, crystalline dislocations in the p-type thermoelectric semiconductor, move away from the heat source, thereby inducing a flow of electrons towards the heat source. This creates a voltage difference that can be used to create a current and power a load. That is, the thermal energy is converted into electrical energy.

There is a class of thermoelectric materials in which the thermoelectric effect is increased when the material is suitably oriented in a magnetic field. While some enhancement of the thermoelectric effect itself is developed by the magnetic field, appropriate mutual orientation of the magnetic field and temperature gradient offers an additional electric current generated by the Nernst or thermomagnetic effect. This latter current is developed in a direction normal to a mutually perpendicular temperature gradient and magnetic field in the material. Prior art seeking to utilise this increased efficiency of heat conversion have relied on placing the thermoelectric material into a magnetic field provided by a permanent magnet located on either side of the material.

While the invention will be described with reference to vessels for the reduction of alumina to aluminium, it is equally applicable to any structures used in pyrometallurgical processes, which in the context of this invention refers to the thermal treatment of minerals, metallic ores and concentrates to bring about physical and/or chemical transformations in order to enable recovery of valuable metals, and includes but is not limited to drying, calcining, roasting, smelting, fuming and refining (including electrolytic processes). Typically, such processes occur at temperatures in excess of 100° C. This invention specifically is applied to any pyrometallurgical processing structure which generates magnetic fields during its operation and this description of the invention is thus not intended to be limited solely to its use in the aluminium industry. Where suitable magnetic fields exist, this invention can also be applied to energy conversion from hot off-gases from pyrometallurgical processes.

By their nature, aluminium refining and smelting processes have significant power requirements. For instance, during reduction of aluminium oxide (alumina) to form aluminium in electrolytic cells, only about 30% of the total power consumed is actually used by the reduction process with a substantial proportion of the remainder being lost as diffuse heat. A modern, large scale aluminium smelting operation may, through the necessary heating of the reduction environment, in turn lose in excess of 600 MW of energy by natural heat fluxes through the sides and top of the reduction vessels as well as off-gases.

Electrolytic cells for the production of aluminium comprise an electrolytic tank having at least one cathode and anode. The electrolytic tank consists of an outer steel shell having carbon cathode blocks sitting on top of a layer of insulation and refractory material along the bottom of the tank. While the precise structure of the side walls varies, a lining comprising a combination of carbon blocks and refractory material is provided against the steel shell. During the electrolytic process, a large electric current is passed from the anode to the cathode (creating a large magnetic field). Aluminium oxide is dissolved in a cryolite bath present in the tank. The operating temperature of the cryolite bath is normally in the range of 930° C. to about 970° C. Much of the energy required to maintain these process temperatures is lost by diffuse heat fluxes through the refractory lining of the tank.

Apart from this heat loss leading to power inefficiency, the heat transfer and subsequent cooling of the cryolite bath against the refractory lining affects the formation of a layer of ‘frozen’ cryolite bath on the inside of the lining of the electrolytic tank. The thickness of this freeze layer/crust/ledge may vary during operation of the cell, depending for instance on cryolite bath temperature (which is responsive to current flow) and heat removal from the outside of the side walls. If the freeze layer becomes too thick it will affect the operation of the cell as the freeze layer will grow on the cathode and disturb the cathodic current distribution. If the freeze layer becomes too thin or is absent in some places, the cryolite bath may attack the refractory lining and ultimately result in its failure (necessitating its replacement to avoid damage to the steel shell and possible spillage of cryolite bath from the tank). Thus, controlled freeze layer formation is essential for good pot operation and long lifetime of the refractory lining within the cell. Controlled development of the freeze layer can be accomplished in part by suitably manipulating the flow of heat from the bath through the refractory lining of the reduction vessel.

Accordingly, the present invention provides a means for utilizing heat energy lost from the surfaces of a pyrometallurgical processing vessel, such as an electrolysis cell, to enhance its electrical efficiency and, in the case of an electrolysis cell, to provide an improved thermodynamic environment on the inside of the vessel lining such that the formation of a freeze lining may be better controlled.

Reference to any prior art in the specification is not, and should not be taken as, an acknowledgment or any form of suggestion that this prior art forms part of the common general knowledge in Australia or any other jurisdiction or that this prior art could reasonably be expected to be ascertained, understood and regarded as relevant by a person skilled in the art.

### BRIEF DESCRIPTION OF THE DRAWINGS

FIG. 1 is an exploded view illustrating one embodiment of a combination thermoelectric/thermomagnetic wafer and its relationship with a heat exchanger panel and further a possible placement of the heat exchanger on a pyrometallurgical processing vessel.

FIG. 2 is a schematic representing an arrangement of the thermoelectric elements and thermomagnetic connectors in a thermoelectric device of the present invention, showing the direction of alignment of the thermoelectric device with respect to a temperature gradient and magnetic field.

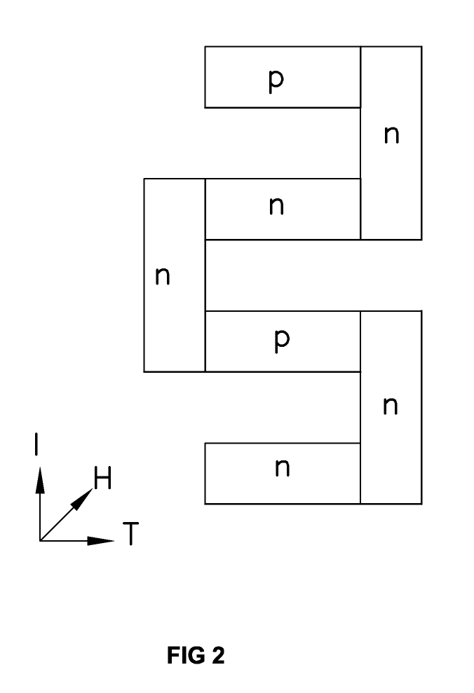

### DETAILED DESCRIPTION OF THE EMBODIMENTS

A preferred embodiment of the invention will now be described with reference to the Figures.

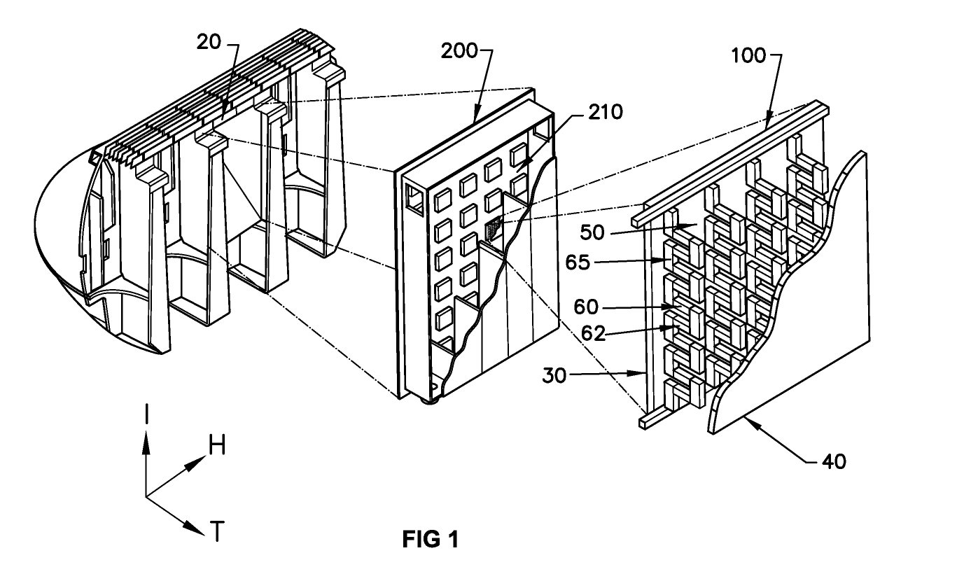

The thermoelectric device 100 shown in FIG. 1 includes a first side 30 (a hot side) and a second side 40 (a cool side), between which there is positioned body portion 50, at least two thermoelectric elements 60, 62, and at least one thermomagnetic connector 65. The elements 60, 62 and 65 need not be arranged as shown in FIG. 1, but may be any combination of series and/or parallel connections (provided the ‘metallic interconnect’ of the n-type thermoelectric element 60 and the p-type thermoelectric 62 element is a thermomagnetic connector 65 made from a thermomagnetic material).

A heat exchanger assembly 200 containing the thermoelectric devices 100 is attached to the surface 20 of the processing vessel. This heat exchanger presents the hot side of the thermoelectric elements 100 to heat leaving the processing vessel by means of any combination of conduction, convection or radiation thereby raising the temperature of the hot side of the element 100. The heat exchanger also provides for the cold side of the thermoelectric elements 100 to be cooled, preferably by radiation or convection provided by a cooling fluid passing through channels within the body of the heat exchanger 200.

The processing structure also has an associated magnetic field. The combination thermoelectric and thermomagnetic wafers 100 located in the heat exchanger are oriented within that heat exchanger so that the thermomagnetic elements 65 within each of the wafers have optimal access to the magnetic field.

The heat transferred from the surface of the vessel to the hot side of the thermoelectric elements and removed by the cooling structures in the heat exchanger produce a temperature gradient through the thermoelectric and thermomagnetic elements thereby providing the driving force for the conversion of a portion of the waste thermal energy to electrical energy.

The material used to construct first side 30 and second side 40 is preferably highly thermally conductive to provide for a more even temperature distribution. To this end, particularly suitable materials are copper or aluminium. The material of the first side may require treatment (coating, anodising, or other method) so as to adopt an emissivity approaching 1 so that radiative heat absorbed by the first side approaches the radiative heat emitted by the surface of the processing vessel. The first side may be of any profile; however a particularly preferred profile is one which allows for heat to be transferred most effectively from the processing vessel to the hot side of the thermoelectric elements. For instance, the first side may include fins to increase the surface area available for convective heat transfer from, and to avoid laminar flow of a fluid which may flow between the surface 20 of the processing vessel and the hot side 30 of the thermoelectric elements mounted in the heat exchanger 200.

The material or materials used to construct the body portion 50 is principally an insulator to inhibit the flow of thermal energy through the material of the body portion of the thermoelectric wafer per se and to increase the amount of thermal energy forced to be transferred through the thermoelectric elements. For instance, the body portion may be made from pre-formed ceramic compacts (alumina, magnesia, zirconia, etc) or other material which would impede the flow of heat and electricity through its matrix. Portions of the body material may however be made to be thermally conductive by means of metallic inserts or other manufacturing techniques in order to optimise the flow of heat through the thermomagnetic connectors 65.

By controlling the type of fluid used as the various fluids passing through the heat exchanger, and their flow rate through spaces within the heat exchanger, it is possible to control (to a degree) the thermal energy being transferred from the processing structure. A greater degree of control may be provided by the incorporation of a heat exchanger type arrangement within these spaces. For example, an internal cooling arrangement as described in PCT/AU2005/001617 may be employed. The controlled cooling of an external surface of the processing structure of the present invention is superior to that presently known in the art. That is, it provides a greater possible degree of cooling with tighter control.

In relation to an electrolytic cell, this enhanced control of the thermal balance within the cell is significant. Most importantly, the outside temperature of the shell of the electrolytic tank can be controlled so that the formation of the ledge/freeze lining can also be controlled. As an example, the fluid flow rates can be controlled in response to the outside temperature of the shell such that if the outside temperature drops the flow rates can also be slowed to result in a reduced transfer of thermal energy from the shell to the thermoelectric device. The flow rates could be controlled by any means known in the art, for instance, a valve or damper system.

The fluid can be gas or liquid. Preferably, the fluid is a gas as this is cheaper to install and safer to operate. For instance, the fluid may be air. The fluid which may flow through a first space between the processing vessel surface and the hot side of the thermoelectric elements will be of a greater temperature than a second fluid flowing past the cold side of the thermoelectric elements. In the first space, the first fluid is heated by the surface of the processing structure conductively and transfers its thermal load to the first side convectively. Heat is also passed to the first side from the surface through radiation transfer. The first side may also include a series of fins or the like that project into the first space to increase the convective transfer of heat. Alternatively, the thermoelectric elements may be mounted directly against the surface of the processing vessel. In the second space, the second fluid is used to remove heat from the second side. The second fluid is preferably at ambient temperatures, but may be cooled. The second side may include a series of fins or the like that project into the second space to increase the convective transfer of heat. The fluids may be propelled through the spaces by any means known in the art. For instance, a fan or blower may be used, and may also be powered by electrical energy produced by the thermoelectric device.

The n-type thermoelectric element 60, p-type thermoelectric elements 62 and thermomagnetic connector 65 may be made from any suitable thermoelectric or thermomagnetic material, respectively, known in the art. Typically, thermoelectric materials are semi-conducting metals or semi-metals. In several common manifestations, the thermoelectric material includes bismuth, lead or gallium compounds which may include lead telluride, lead selenide, bismuth antimony, gallium arsenide and gallium phosphide. Preferably, the materials selected are ones that can operate at high temperatures, such as between 100° C. and about 500° C.

In FIG. 1, the thermoelectric elements are shown in direct contact with the thermomagnetic connectors. Preferably however, the thermoelectric elements are in electrical contact with the thermomagnetic connectors by any means known in the art, for instance by electrically conductive wiring, welding or otherwise joining.

To enhance the thermoelectric effect, the device, which as discussed consists of thermomagnetic as well as thermoelectric material, is placed in a magnetic field so that the direction of heat flow, the direction of current flow in the thermomagnetic elements and the magnetic field are orthogonally aligned. If the device is aligned as in FIG. 1 so that direction of magnetic field is in the plane of the matrix of wafers across the thermoelectric device, and the heat flow from the processing structure is away from the processing structure surface 20 into the hot face side of the device (eg 30), then the current will run up and down the panel thermoelectric device (whether it runs up or down will depend on whether the thermomagnetic connectors are n-type thermomagnetic semiconductors or p-type thermomagnetic semiconductors. This current is enhanced due to the properties of the thermomagnetic material when the magnetic field is aligned as described above when compared with when the magnetic field is in another direction.

The thermoelectric elements, or wafers, are aligned in an insulating support panel, body portion 50. The thermoelectric elements alternate between p-type and n-type semiconductor materials electrically connected through the support panel by thermomagnetic connectors. The thermomagnetic connectors are either n-type or p-type semiconductor materials in any one direction orthogonal to both the temperature gradient and the magnetic field. The insulating support panel is covered on both the hot side 30 and cool side 40 by a layer of thermally conductive diffuser material, such as aluminium, which assists in providing an even temperature across the surface of the thermoelectric device and particularly avoids hot spots forming.

It will be understood that the invention disclosed and defined in this specification extends to all alternative combinations of two or more of the individual features mentioned or evident from the text or drawings. All of these different combinations constitute various alternative aspects of the invention.

1. A method for utilizing heat energy from a surface (20) of a pyrometallurgical processing structure, the method comprising
providing at least one thermoelectric element in thermal communication with the surface of the structure, the thermoelectric element including at least one n-type thermoelectric semiconductor (60) and at least one p-type thermoelectric semiconductor (62);
based on the direction of the magnetic field generated by the operation of the structure, providing at least one thermomagnetic connector (65), the at least one thermomagnetic connector (65) being (a) positioned such that a temperature gradient exists or is established across the thermomagnetic connector (65), the temperature gradient being created by heat originating from the surface of the processing structure, (b) within the magnetic field so that the magnetic field increases the efficiency of the thermomagnetic connector (65), and (c) in electrical communication with at least one thermoelectric element; and
collecting the electrical energy thereby generated by the thermoelectric elements and the thermomagnetic connectors (65).

2. The method of claim 1 wherein each thermomagnetic connector (65) is in electrical communication with at least one n-type thermoelectric semiconductor (60) and at least one p-type thermoelectric semiconductor (62).

3. The method of claim 1 wherein each thermomagnetic connector (65) provides substantially the only electrical communication between an n-type thermoelectric semiconductor (60) and a p-type thermoelectric semiconductor (62).

4. The method of claim 1 wherein each thermomagnetic connector is a metallic interconnect between an n-type thermoelectric semiconductor (60) and an p-type thermoelectric semiconductor (62).

5. The method of claim 1 wherein each thermomagnetic connector is either an n-type thermomagnetic semiconductor (60) or a p-type thermomagnetic semiconductor (62).

6. The method of claim 1 wherein all thermomagnetic connectors (65) substantially linearly positioned in the same direction are either an n-type thermomagnetic semiconductor (60) or a p-type thermomagnetic semiconductor (62).

7. The method of claim 1 wherein the thermoelectric elements form an alternating series of n-type thermoelectric semiconductors (60) and p-type thermoelectric semiconductors (62), and each thermoelectric semiconductor is in electric communication with the adjacent thermoelectric semiconductor via a thermomagnetic connector (65).

8. The method of claim 1 wherein the thermomagnetic connector (65) is aligned in the magnetic field such that the electrical energy produced by the thermomagnetic connector (65) is increased.

9. The thermoelectric device of claim 1 wherein the processing structure is an electrolytic cell.

10. The thermoelectric device of claim 9 wherein the electrolytic cell is for the production of aluminium.

11. A thermoelectric device (100) for the conversion of heat energy from a surface (20) of a processing structure to electrical energy, the thermoelectric device
(a) being adapted to engage with the structure such that there is thermal communication between the processing structure and the thermoelectric device (100); and
(b) comprising
(i) at least one thermoelectric element including at least one n-type thermoelectric semiconductor (60) and at least one p-type thermoelectric semiconductor (62),
(ii) at least one thermomagnetic connector (65) in electrical communication with at least one thermoelectric element, the thermomagnetic connector (65) aligned in a magnetic field associated with the structure to provide greater electrical energy from the thermoelectric device (100) than in the absence of the magnetic field.

12. A method for utilizing heat energy from a surface (20) of a pyrometallurgical processing structure, the method comprising
providing at least one thermoelectric element in thermal communication with the surface of the structure, the thermoelectric element including at least one n-type thermoelectric semiconductor (60) and at least one p-type thermoelectric semiconductor (62);
based on the direction of the magnetic field generated by the operation of the structure, providing at least one thermomagnetic connector (65), the at least one thermomagnetic connector (65) being (a) positioned such that a temperature gradient exists or is established across the thermomagnetic connector (65), the temperature gradient being created by heat originating from the surface of the processing structure, (b) within the magnetic field so that the magnetic field increases the efficiency of the thermomagnetic connector (65), (c) in electrical communication with at least one thermoelectric element wherein all thermomagnetic connectors (65) substantially linearly positioned in the same direction are either an n-type thermomagnetic semiconductor (60) or a p-type thermomagnetic semiconductor (62); and
collecting the electrical energy thereby generated by the thermoelectric elements (60, 62) and the thermomagnetic connectors (65).
